(19) United States
(12) Patent Application Publication
(10) Pub. No.: US 2026/0271644 A1
(43) Pub. Date: Sep. 10, 2026

(54) SUBSTRATE PROCESSING METHOD

(71) Applicant: Tokyo Electron Limited, Tokyo (JP)

(72) Inventors: Rintaro HIGUCHI, Kumamoto (JP); Koji KAGAWA, Kumamoto (JP)

(73) Assignee: Tokyo Electron Limited, Tokyo (JP)

(21) Appl. No.: 19/164,596

(22) PCT Filed: May 1, 2024
(86) PCT No.: PCT/JP2024/016767

§ 371 Date: Sep. 12, 2025

(30) Foreign Application Priority Data
May 15, 2023 (JP) 2023-080237

(51) Int. Cl. H10P 50/66; H10D 64/01; H10P 50/68; H10P 72/00

(52) U.S. Cl. CPC H10P 50/667; H10D 64/013; H10P 50/683; H10P 72/0424; H10P 72/0454

(57) ABSTRACT

A substrate processing method includes a first etching process including supplying a first etching liquid to a substrate on which a gate electrode and a work function adjusting film that adjusts a work function of the gate electrode are formed, and etching the work function adjusting film. The first etching process includes supplying hydrofluoric acid, mixed solution of sulfuric acid and hydrogen peroxide (SPM), or mixed solution of ammonia and hydrogen peroxide (SC1) to the substrate as the first etching liquid.

### CROSS-REFERENCE TO RELATED APPLICATIONS

This application is national stage application of International Application No. PCT/JP2024/016767, filed on May 1, 2024, which designates the United States, incorporated herein by reference, and which claims the benefit of priority from Japanese Patent Application No. 2023-080237, filed on May 15, 2023, the entire contents of each are incorporated herein by reference.

### FIELD

An exemplary embodiment disclosed herein relates to a substrate processing method.

### BACKGROUND

In recent years, there has been developed a semiconductor device including a so-called transistor having a nanosheet structure. In such a transistor having a nanosheet structure, for example, a word function adjusting film is used, which is for adjusting a work function of a gate electrode (Japanese Laid-open Patent Publication No. 2022-105298).

### SUMMARY

### Solution to Problem

A substrate processing method according to an embodiment of the present disclosure includes a first etching process including supplying a first etching liquid to a substrate on which a gate electrode and a work function adjusting film that adjusts a work function of the gate electrode are formed, and etching the work function adjusting film. The first etching process includes supplying hydrofluoric acid, mixed solution of sulfuric acid and hydrogen peroxide (SPM), or mixed solution of ammonia and hydrogen peroxide (SC1) to the substrate as the first etching liquid.

### BRIEF DESCRIPTION OF DRAWINGS

FIG. 1 is a diagram illustrating a schematic configuration of a substrate processing system according to an embodiment.

FIG. 2 is a diagram illustrating one example of a specific configuration of a process unit according to the embodiment.

FIG. 3 is an enlarged cross-sectional view illustrating one example of a surface structure of a wafer to be a target for substrate processing according to the embodiment.

FIG. 4 is a flowchart illustrating one example of a procedure for substrate processing to be executed by the substrate processing system according to the embodiment.

FIG. 5 is a flowchart illustrating one example of a procedure for a periphery portion etching process and a back surface etching process to be executed by the substrate processing system according to the embodiment.

FIG. 6 is a diagram illustrating film thicknesses of functional films before processing, and after a first etching process.

FIG. 7 is a diagram illustrating film thicknesses of the functional films before processing, after the first etching process, after a second etching process, and after third and fourth etching processes.

### DESCRIPTION OF EMBODIMENTS

An exemplary embodiment of a substrate processing method disclosed in the present application will be described below in detail with reference to the accompanying drawings. In addition, the illustrative embodiment disclosed below is not intended to limit the present invention. It should be noted that the drawings are schematic, and the relationship between the dimensions of each element, the ratio of each element, and the like may differ from the actual situation. Even between the drawings, there are cases in which portions having different dimensional relationships and ratios are included.

In recent years, there has been developed a semiconductor device including a so-called transistor having a nanosheet structure. In such a transistor having a nanosheet structure, for example, a word function adjusting film is used, which is for adjusting a work function of a gate electrode.

However, there has been room for further improvement in a technology for efficiently executing an etching process of a work function adjusting film that is formed on a substrate. Thus, in some cases, it is difficult to efficiently remove a work function adjusting film that is formed on a back surface and/or a periphery portion of a substrate.

Thus, the realization of the technology has been desired, which is capable of overcoming the above-mentioned problem so as to efficiently etch a work function adjusting film that is formed on a substrate.

### <Outline of Substrate Processing System>

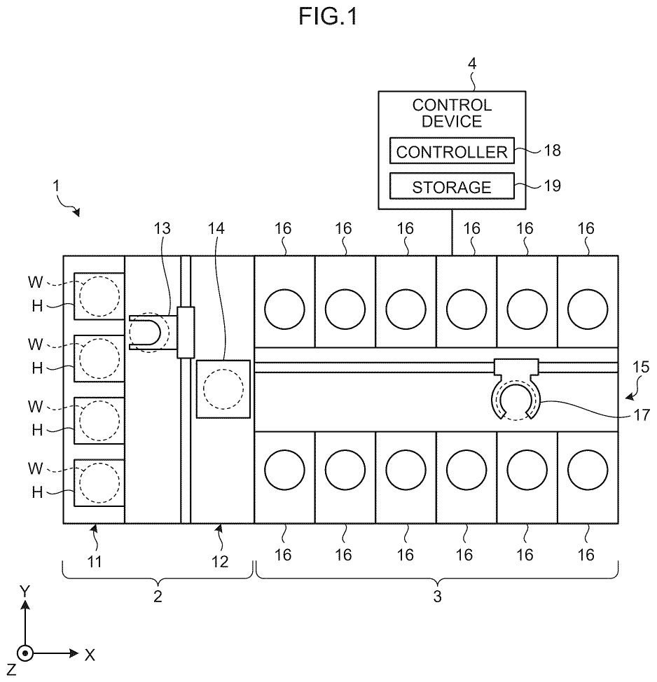

First, with reference to FIG. 1, a schematic configuration of a substrate processing system 1 according to the embodiment will be explained. FIG. 1 is a diagram illustrating the schematic configuration of the substrate processing system 1 according to the embodiment. Hereinafter, in order to clarify positional relation, an X-axis, a Y-axis, and a Z-axis are defined, which are perpendicular to one another, and further a positive Z-axis direction is defined as an upward direction in the vertical direction.

As illustrated in FIG. 1, the substrate processing system 1 includes a carry-in/out station 2 and a processing station 3. The carry-in/out station 2 and the processing station 3 are provided adjacent to each other.

The carry-in/out station 2 includes a FOUP placing section 11 and a transfer section 12. In the FOUP placing section 11, a plurality of FOUPs H is placed to horizontally accommodate a plurality of substrates, namely, semiconductor wafers W according to the embodiment (hereinafter, may be referred to as wafers W).

The transfer section 12 is provided adjacent to the FOUP placing section 11, and includes therein a substrate transfer device 13 and a delivery unit 14. The substrate transfer device 13 includes a wafer holding mechanism configured to hold the wafer W. The substrate transfer device 13 is movable horizontally and vertically and is pivotable around a vertical axis, and transfers the wafer W between the corresponding FOUP H and the delivery unit 14 by using the wafer holding mechanism.

The processing station 3 is provided adjacent to the transfer section 12. The processing station 3 includes a transfer section 15 and a plurality of process units 16. The plurality of process units 16 is provided side by side on both sides of the transfer section 15.

The transfer section 15 includes therein a substrate transfer device 17. The substrate transfer device 17 includes a wafer holding mechanism configured to hold the wafer W. The substrate transfer device 17 is movable horizontally and vertically and is pivotable around the vertical axis, and transfers the wafer W between the delivery unit 14 and the corresponding process unit 16 by using the wafer holding mechanism.

Each of the process units 16 performs predetermined substrate processing on the wafer W transferred by the substrate transfer device 17.

The substrate processing system 1 further includes a control device 4. The control device 4 is a computer, for example, so as to include a controller 18 and a storage 19. The storage 19 stores therein a program for controlling various types of processes that are performed in the substrate processing system 1. The controller 18 reads out and executes the program stored in the storage 19 to control operations of the substrate processing system 1.

The program may be recorded in a computer-readable recording medium and thus may be installed into the storage 19 of the control device 4 from the recording medium. A computer-readable recording medium includes, for example, a hard disk (HD), a flexible disk (FD), a compact disc (CD), a magneto-optical disk (MO), and a memory card among other things.

In the substrate processing system 1 configured as described above, the substrate transfer device 13 of the carry-in/out station 2 first takes out the wafer W from one of the FOUPs H placed in the FOUP placing section 11, and places the taken wafer W on the delivery unit 14. The wafer W placed on the delivery unit 14 is taken out from the delivery unit 14 by the substrate transfer device 17 of the processing station 3, and is carried into one of the process units 16.

The wafer W carried into the process unit 16 is processed by the process unit 16, and then is carried out from the process unit 16 and placed on the delivery unit 14 by using the substrate transfer device 17. Next, the processed wafer W placed on the delivery unit 14 is returned to the corresponding FOUP H in the FOUP placing section 11 by using the substrate transfer device 13.

### <Configuration of Process Unit>

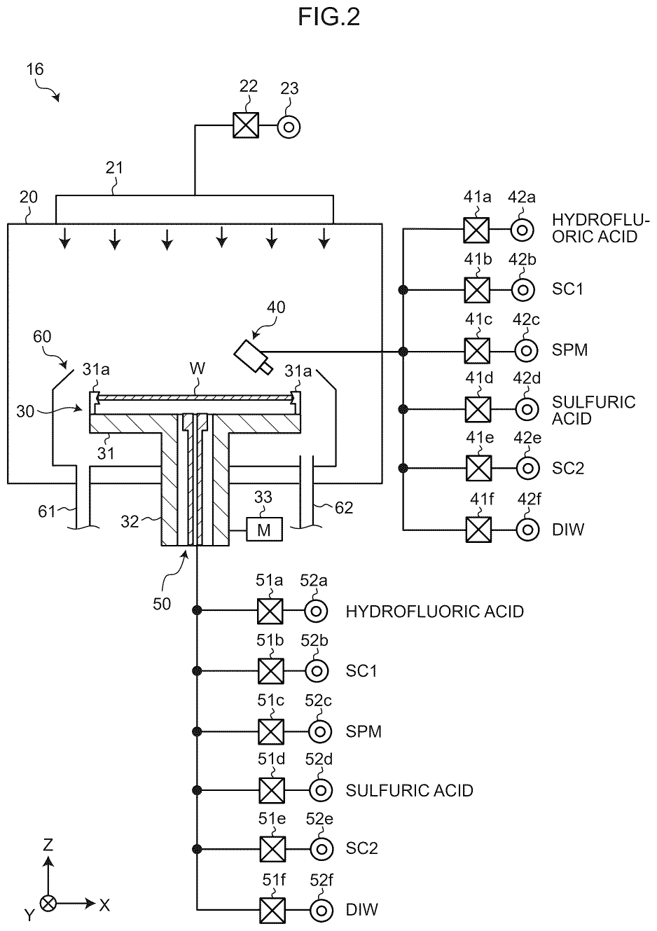

Next, a configuration of the process unit 16 according to the embodiment will be explained with reference to FIG. 2. FIG. 2 is a schematic diagram illustrating one example of a specific configuration of the process unit 16. As illustrated in FIG. 2, the process unit 16 includes a chamber 20, a substrate processing unit 30, a periphery portion supply unit 40, a back surface supply unit 50, and a recovery cup 60.

The chamber 20 accommodates therein the substrate processing unit 30, the periphery portion supply unit 40, the back surface supply unit 50, and the recovery cup 60. A Fan Filter Unit (FFU) 21 is provided in a ceiling portion of the chamber 20. The FFU 21 forms a down flow in the chamber 20.

The FFU 21 is connected to a downflow-gas supplying source 23 via a flow controller 22. The FFU 21 discharges a downflow gas (for example, nitrogen, dry air, or the like) into the chamber 20, which is supplied from the downflow-gas supplying source 23. The flow controller 22 adjusts a flow volume of the downflow gas to be supplied to the FFU 21. The flow controller 22 includes an open/close valve, a flow volume controlling valve, a flowmeter, etc.

The substrate processing unit 30 includes a holding unit 31, a supporting unit 32, and a drive unit 33 so as to perform predetermined substrate processing on the placed wafer W. The holding unit 31 horizontally holds the wafer W. A plurality of gripping units 31a is provided on an upper surface of the holding unit 31, each of which grips a periphery portion of the wafer W.

The wafer W is horizontally held by the gripping units 31a in a state where the wafer W is slightly separated from the upper surface of the holding unit 31. Note that the wafer W is held by the holding unit 31 in a state where a surface thereof faces upward, on which various semiconductor devices are formed.

The supporting unit 32 is a member that extends in a vertical direction so as to support the holding unit 31 from below. The drive unit 33 rotates the supporting unit 32 around a vertical axis.

The substrate processing unit 30 rotates the supporting unit 32 by using the drive unit 33 so as to rotate the holding unit 31 supported by the supporting unit 32, thereby rotating the wafer W held by the holding unit 31.

The periphery portion supply unit 40 supplies various types of processing liquids to a periphery portion of the wafer W held by the substrate processing unit 30. The periphery portion supply unit 40 is connected to a hydrofluoric acid supply source 42a via a flow controller 41a. The hydrofluoric acid supply source 42a is a tank for retaining therein hydrofluoric acid, for example. The flow controller 41a adjusts a flow volume of hydrofluoric acid to be supplied to the periphery portion supply unit 40. The flow controller 41a includes an open/close valve, a flow volume controlling valve, a flowmeter, etc.

Furthermore, the periphery portion supply unit 40 is connected to an SC1 supply source 42b via a flow controller 41b. The SC1 supply source 42b is a tank for retaining therein SC1 (namely, mixed solution of ammonia and hydrogen peroxide), for example. The flow controller 41b adjusts a flow volume of SC1 to be supplied to the periphery portion supply unit 40. The flow controller 41b includes an open/close valve, a flow volume controlling valve, a flowmeter, etc.

Furthermore, the periphery portion supply unit 40 is connected to an SPM supply source 42c via a flow controller 41c. The SPM supply source 42c is a tank for retaining therein SPM (namely, mixed solution of sulfuric acid and hydrogen peroxide), for example. The flow controller 41c adjusts a flow volume of SPM to be supplied to the periphery portion supply unit 40. The flow controller 41c includes an open/close valve, a flow volume controlling valve, a flowmeter, etc.

Furthermore, the periphery portion supply unit 40 is connected to a sulfuric acid supply source 42d via a flow controller 41d. The sulfuric acid supply source 42d is a tank for retaining therein a sulfuric acid, for example. The flow controller 41d adjusts a flow volume of a sulfuric acid to be supplied to the periphery portion supply unit 40. The flow controller 41d includes an open/close valve, a flow volume controlling valve, a flowmeter, etc.

Furthermore, the periphery portion supply unit 40 is connected to an SC2 supply source 42e via a flow controller 41e. The SC2 supply source 42e is a tank for retaining therein SC2 (namely, mixed solution of hydrochloric acid and hydrogen peroxide), for example. The flow controller 41e adjusts a flow volume of SC2 to be supplied to the periphery portion supply unit 40. The flow controller 41e includes an open/close valve, a flow volume controlling valve, a flowmeter, etc.

Furthermore, the periphery portion supply unit 40 is connected to a DIW supply source 42f via a flow controller 41f. The DIW supply source 42f is a tank for retaining therein deionized water (namely, DIW), for example. The flow controller 41f adjusts a flow volume of DIW to be supplied to the periphery portion supply unit 40. The flow controller 41f includes an open/close valve, a flow volume controlling valve, a flowmeter, etc. The above-mentioned DIW is used in a rinsing process to be executed on the wafer W, for example.

The back surface supply unit 50 supplies various types of processing liquids to a back surface of the wafer W that is held by the substrate processing unit 30. The back surface supply unit 50 is inserted into hollow portions of the holding unit 31 and the supporting unit 32. A flow path is formed in the back surface supply unit 50, which extends in a vertical direction.

The above-mentioned flow path is connected to a hydrofluoric acid supply source 52a via a flow controller 51a. The hydrofluoric acid supply source 52a is a tank for retaining therein hydrofluoric acid, for example. The flow controller 51a adjusts a flow volume of hydrofluoric acid to be supplied to the back surface supply unit 50. The flow controller 51a includes an open/close valve, a flow volume controlling valve, a flowmeter, etc.

The flow path that is formed in the back surface supply unit 50 is connected to an SC1 supply source 52b via a flow controller 51b. The SC1 supply source 52b is a tank for retaining therein SC1, for example. The flow controller 51b adjusts a flow volume of SC1 to be supplied to the back surface supply unit 50. The flow controller 51b includes an open/close valve, a flow volume controlling valve, a flowmeter, etc.

The flow path that is formed in the back surface supply unit 50 is connected to an SPM supply source 52c via a flow controller 51c. The SPM supply source 52c is a tank for retaining therein SPM, for example. The flow controller 51c adjusts a flow volume of SPM to be supplied to the back surface supply unit 50. The flow controller 51c includes an open/close valve, a flow volume controlling valve, a flowmeter, etc.

The flow path that is formed in the back surface supply unit 50 is connected to a sulfuric acid supply source 52d via a flow controller 51d. The sulfuric acid supply source 52d is a tank for retaining therein sulfuric acid, for example. The flow controller 51d adjusts a flow volume of sulfuric acid to be supplied to the back surface supply unit 50. The flow controller 51d includes an open/close valve, a flow volume controlling valve, a flowmeter, etc.

The flow path that is formed in the back surface supply unit 50 is connected to an SC2 supply source 52e via a flow controller 51e. The SC2 supply source 52e is a tank for retaining therein SC2, for example. The flow controller 51e adjusts a flow volume of SC2 to be supplied to the back surface supply unit 50. The flow controller 51e includes an open/close valve, a flow volume controlling valve, a flowmeter, etc.

The flow path that is formed in the back surface supply unit 50 is connected to a DIW supply source 52f via a flow controller 51f. The DIW supply source 52f is a tank for retaining therein DIW, for example. The flow controller 51f adjusts a flow volume of DIW to be supplied to the back surface supply unit 50. The flow controller 51f includes an open/close valve, a flow volume controlling valve, a flowmeter, etc.

The recovery cup 60 is arranged so as to surround the holding unit 31, and collects processing liquid that is splashed from the wafer W by rotation of the holding unit 31. A drain port 61 is formed on a bottom portion of the recovery cup 60, and the processing liquid collected by the recovery cup 60 is discharged from the above-mentioned drain port 61 to an outside of the process unit 16. Furthermore, an exhaust port 62 is formed on a bottom portion of the recovery cup 60, which is for exhausting a gas supplied from the FFU 21 to the outside of the process unit 16.

### <Details of Substrate Processing>

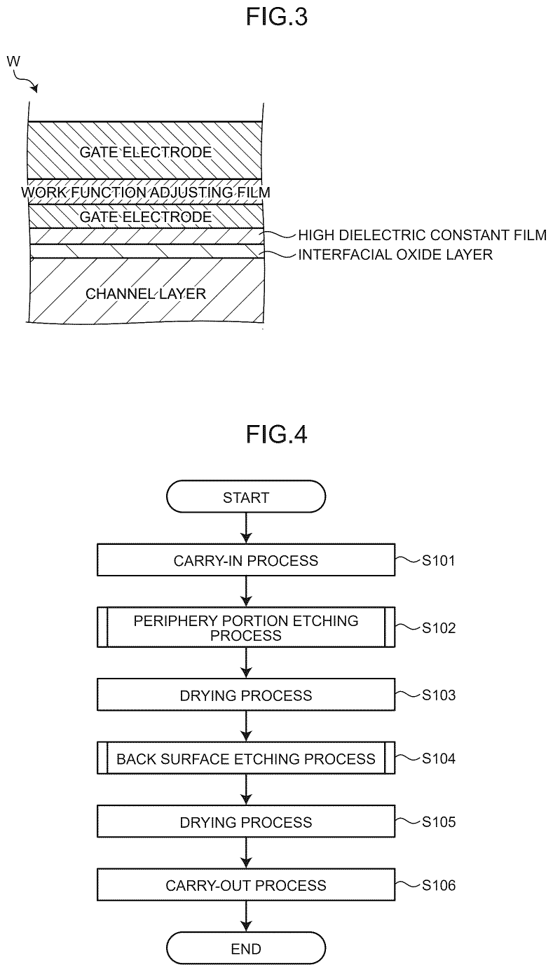

Next, details of substrate processing according to the embodiment will be explained with reference to FIGS. 3 to 7. FIG. 3 is an enlarged cross-sectional view illustrating one example of a surface structure of the wafer W to be a target for the substrate processing according to the embodiment.

As illustrated in FIG. 3, on a surface of the wafer W according to the embodiment, an interfacial oxide layer, a high dielectric constant film, a gate electrode, a work function adjusting film, and a gate electrode are sequentially laminated on a channel layer in this order.

The channel layer is made of silicon into which predetermined amounts of various dopants are injected so as to function as a channel of a transistor. The interfacial oxide layer is made of an oxide of a constituent element of the channel layer (SiO₂ (oxide silicon), for example) etc.

The high dielectric constant film is made of an element having a high dielectric constant so as to function as a gate insulation film of the transistor. The high dielectric constant film according to the embodiment includes one of HfOₓ (hafnium oxide), HfSiOₓ (hafnium silicate), and LaOₓ (lanthanum oxide).

The gate electrode functions as a gate electrode of the transistor. The gate electrode according to the embodiment includes TiN (titanium nitride), for example.

The work function adjusting film adjusts a work function of the gate electrode to a desired value. Furthermore, the work function adjusting film according to embodiment may also function as the gate electrode of the transistor. The work function adjusting film according to the embodiment includes one of CeC (cerium carbide), TiAlC (titanium-aluminum carbide), and TaC (tantalum carbide).

In the embodiment, as illustrated in FIG. 3, it is preferable that the work function adjusting film be sandwiched between a pair of gate electrodes. Thus, it is possible to configure a high-performance transistor.

FIG. 4 is a flowchart illustrating one example of a procedure for substrate processing to be executed by the substrate processing system 1 according to the embodiment. In the substrate processing according to the embodiment, the controller 18 first controls the transfer sections 12 and 15 etc. so as to carry the wafer W into the process unit 16 (Step S101).

Note that when carrying the wafer W into the process unit 16, the controller 18 acquires types of first to fourth etching liquids for etching respective functional films illustrated in FIG. 3 on the basis of FOUP IDs that are marked on the FOUPs H (see FIG. 1) and the like.

Next, the controller 18 controls the periphery portion supply unit 40 etc. so as to execute a periphery portion etching process for etching the gate electrode, the work function adjusting film, the high dielectric constant film, and the interfacial oxide layer that are formed on a periphery portion of the wafer W (Step S102). Details of the above-mentioned periphery portion etching process will be mentioned later.

Next, the controller 18 controls the substrate processing unit 30 etc. so as to execute a drying process on the wafer W by spin drying (Step S103).

Next, the controller 18 controls the back surface supply unit 50 etc. so as to execute a back surface etching process for etching the gate electrode, the work function adjusting film, the high dielectric constant film, and the interfacial oxide layer that are formed on a back surface of the wafer (Step S104). Details of the above-mentioned etching process will be mentioned later.

Next, the controller 18 controls the substrate processing unit 30 etc. so as to execute a drying process on the wafer W by spin drying (Step S105). Finally, the controller 18 controls the transfer sections 12 and 15 etc. so as to carry the wafer W out of the process unit 16 (Step S106), and thus ends a series of substrate processing.

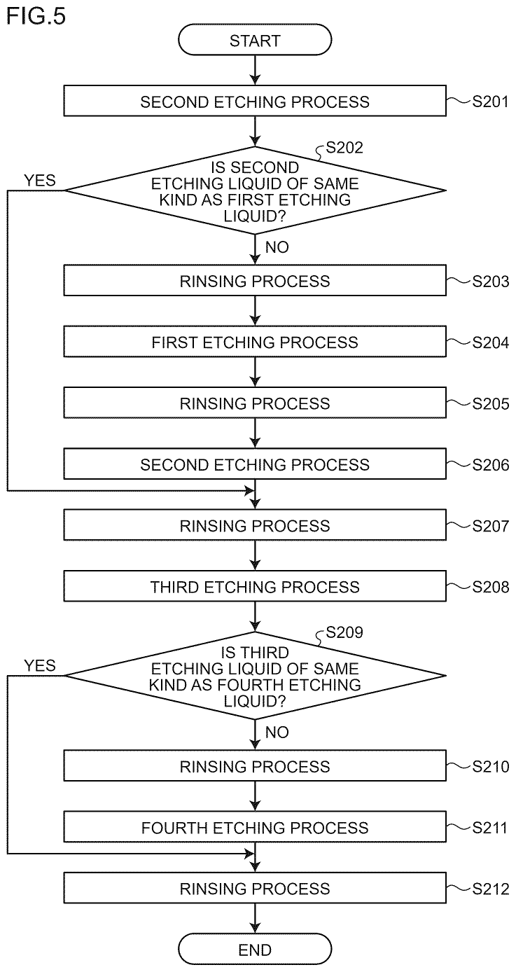

FIG. 5 is a flowchart illustrating one example of a procedure for the periphery portion etching process and the back surface etching process to be executed by the substrate processing system 1 according to the embodiment. Note that, in the embodiment, the procedure for the periphery portion etching process and the procedure for the back surface etching process are basically the same except that discharging target locations of the processing liquid are different. Thus, in the following explanation, the procedure for the periphery portion etching process alone will be explained while the procedure for the back surface etching process is omitted.

As illustrated in FIG. 5, in the periphery portion etching process according to the embodiment, the controller 18 first executes a second etching process for etching a gate electrode that is exposed in a periphery portion surface of the wafer W (Step S201).

The second etching process according to the embodiment includes discharging a second etching liquid containing SC1 onto the periphery portion of the wafer W so as to etch the gate electrode located on the periphery portion. In the above-mentioned second etching process, a chemical reaction expressed by the following formula (1) occurs, so that the gate electrode made of TiN is efficiently etched.

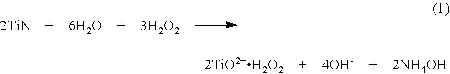

Furthermore, in a case where SC1 is used as the second etching liquid, a mixed ratio of “NH₄OH:H₂O₂:H₂O” is preferably from “1:1:5” to “1:10:3”, and temperatures thereof are preferably from 15° C. to 80° C. In other words, in a case where SC1 is used as the second etching liquid, the desirable mixed ratio is from “NH₄OH 3.69 (wt %) and H₂O₂ 4.92 (wt %)” to “NH₄OH 1.72 (wt %) and H₂O₂ 22.98 (wt %)”. Thus, it is possible to further efficiently etch the gate electrode made of TiN.

Next, the controller 18 determines whether or not the second etching liquid used in the process in Step S201 is of the same kind as a first etching liquid for etching a work function adjusting film (Step S202).

In a case where the second etching liquid and the first etching liquid are not the same kind (Step S202: No), the controller 18 discharges DIW onto the periphery portion of the wafer W on which the second etching process has been executed, so as to execute a rinsing process on the periphery portion of the wafer W (Step S203).

Next, the controller 18 executes a first etching process for etching the work function adjusting film exposed to the periphery portion surface of the wafer W by the second etching process (Step S204).

The first etching process according to the embodiment includes discharging the first etching liquid onto the periphery portion of the wafer W so as to etch the work function adjusting film located on the periphery portion. In the above-mentioned first etching process, in a case where the work function adjusting film is CeC, it is preferable that hydrofluoric acid be used as the first etching liquid.

In this case, a chemical reaction expressed by the following formula (2) occurs, so that the work function adjusting film made of CeC is efficiently etched.

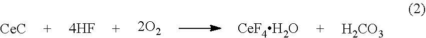

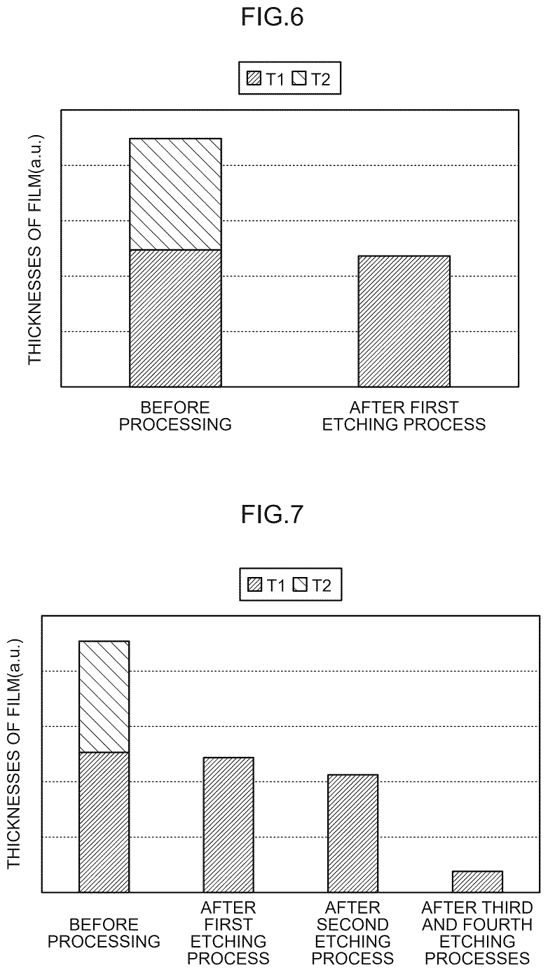

FIG. 6 illustrates test result of the above-mentioned etching of a CeC film with the use of hydrofluoric acid as illustrated herein. FIG. 6 is a diagram illustrating film thicknesses of functional films before processing, and after the first etching process. In the test result illustrated in FIG. 6, a sample was used as a test sample, which was obtained by sequentially laminating an SiO₂ film having a thickness of 10 (Å), an HfOₓ film having a thickness of to be 20 (Å) thick, a TiN film having a thickness of 19 (Å) thick, and a CeC having a thickness of 40 (Å) from an Si substrate.

Furthermore, film thicknesses of functional films before and after the etching test were measured by using an optical film thickness gauge (Aleris 8350, KLA Corporation). Note that in the above-mentioned film thickness measurement, a film thickness is evaluated while assuming the SiO₂ film, the HfOₓ film, and the TiN film as one film T1, and further a film thickness is evaluated while assuming the CeC film as another film T2.

Furthermore, in the test results illustrated in FIG. 6, in the first etching process, the first etching liquid was used, which is obtained by mixing an undiluted solution of hydrofluoric acid (50 wt %) and DIW in a volume ratio of 1:50 and by adjusting a temperature thereof to 50° C. An etching time interval of the above-mentioned first etching process was 30 seconds.

As illustrated in FIG. 6, it can be understood that using hydrofluoric acid as the first etching liquid makes it possible to efficiently etch the work function adjusting film (see film T2 illustrated in FIG. 6) made of CeC.

Returning to FIG. 5. In a case where the work function adjusting film is CeC in the first etching process, SPM may be used as the first etching liquid. In this case, a chemical reaction expressed by the following formula (3) occurs, so that the work function adjusting film made of CeC is efficiently etched.

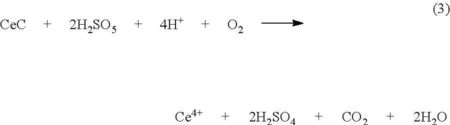

In the above-mentioned first etching process, in a case where the work function adjusting film is TiAlC, it is preferable that hydrofluoric acid be used as the first etching liquid. In this case, a chemical reaction expressed by the following formula (4) occurs, so that the work function adjusting film made of TiAlC is efficiently etched.

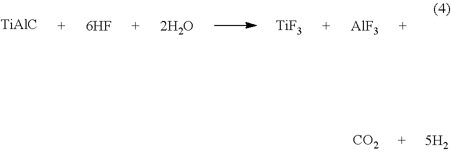

As described above, in the embodiment, hydrofluoric acid or SPM is used as the first etching liquid in the first etching process for etching the work function adjusting film, so that it is possible to efficiently etch the work function adjusting film made of CeC or TiAlC.

Furthermore, in a case where hydrofluoric acid is used as the first etching liquid, it is preferable that a hydrofluoric acid concentration be from 0.57 wt % to 50 wt %, and a temperature thereof be from 20° C. to 80° C. Thus, it is possible to further efficiently etch the work function adjusting film made of TiAlC.

Furthermore, in a case where SPM is used as the first etching liquid, a mixed ratio of “H₂SO₄:H₂O₂” is preferably from “1:1” to “10:1”, and a temperature thereof is preferably from 50° C. to 130° C. In other words, in a case where SPM is used as the first etching liquid, the desirable mixed ratio is from “H₂SO₄ 59.9 (wt %) and H₂O₂ 11.7 (wt %)” to “H₂SO₄ 90.5 (wt %) and H₂O₂ 1.8 (wt %)”. Thus, it is possible to further efficiently etch the work function adjusting film made of CeC.

Subsequent to the first etching process that has been explained so far, the controller 18 discharges DIW onto a periphery portion of the wafer W on which the first etching process has been executed, and further executes a rinsing process on the periphery portion of the wafer W (Step S205).

Next, the controller 18 executes a second etching process for etching a gate electrode exposed from a periphery portion surface of the wafer W (Step S206). The above-mentioned process in Step S206 is similar to the above-mentioned process in Step S201, and therefore detailed explanation thereof is omitted.

Next, the controller 18 discharges DIW onto the periphery portion of the wafer W on which the second etching process has been executed, and further executes a rinsing process on the periphery portion of the wafer W (Step S207).

Note that in a case where the second etching liquid and the first etching liquid are of the same kind in the above-mentioned process in Step S202 (Step S202: Yes), the processing is shifted to in Step S207.

In a case where the work function adjusting film is TaC, for example, SC1 is preferable as the first etching liquid for etching the above-mentioned TaC, which is liquid of the same kind as the second etching liquid.

In this case, a chemical reaction expressed by the following formula (5) occurs, so that the work function adjusting film made of TaC is efficiently etched.

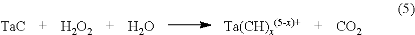

Furthermore, in a case where the second etching liquid and the first etching liquid are of the same kind, in a case where the process in Step S201 is continuously executed, it is possible to continuously execute an etching process on a gate electrode, a work function adjusting film, and another gate electrode, which are located on a surface of the wafer W. Thus, the processes in Steps S203 to S206 can be omitted.

In other words, in a case where the second etching liquid and the first etching liquid are of the same kind, it is possible to execute both of the second etching process and the first etching process by the process in Step S201.

In the embodiment, by using SC1 as the first etching liquid in the first etching process for etching the work function adjusting film, it is possible to efficiently etch the work function adjusting film made of TaC.

Furthermore, in a case where SC1 is used as the first etching liquid, a mixed ratio of “NH₄OH:H₂O₂:H₂O” is preferably from “1:1:5” to “1:10:3”, and a temperature thereof is preferably from 15° C. to 80° C. In other words, in a case where SC1 is used as the first etching liquid, the desirable mixed ratio is from “NH₄OH 3.69 (wt %) and H₂O₂ 4.92 (wt %)” to “NH₄OH 1.72 (wt %) and H₂O₂ 22.98 (wt %)”. Thus, it is possible to further efficiently etch the work function adjusting film made of TaC.

Subsequent to the rinsing process in Step S207, the controller 18 executes a third etching process for second execution of the first etching process so as to etch a high dielectric constant film exposed in a periphery portion surface of the wafer W (Step S208).

The third etching process according to the embodiment includes discharging the third etching liquid onto the periphery portion of the wafer W so as to etch the high dielectric constant film located on the periphery portion. In the above-mentioned third etching process, in a case where the high dielectric constant film is HfOₓ, it is preferable that hydrofluoric acid be used as the third etching liquid.

In this case, for example, a chemical reaction expressed by the following formula (6) occurs, so that the high dielectric constant film made of HfOₓ is efficiently etched.

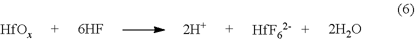

Furthermore, in the above-mentioned third etching process, in a case where the high dielectric constant film is HfSiOₓ, it is preferable that hydrofluoric acid be used as the third etching liquid. In this case, for example, a chemical reaction expressed by the following formula (7) occurs, so that the high dielectric constant film made of HfSiOₓ is efficiently etched.

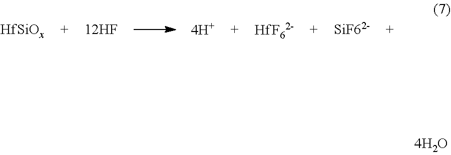

Furthermore, in the above-mentioned third etching process, in a case where the high dielectric constant film is LaOₓ, it is preferable that sulfuric acid or SC2 be used as the third etching liquid. In this case, for example, a chemical reaction expressed by the following formula (8) occurs, so that the high dielectric constant film made of LaOₓ is efficiently etched.

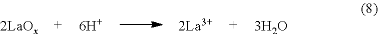

As described above, in the embodiment, hydrofluoric acid, sulfuric acid or SC2 is used as the third etching liquid in the third etching process for etching the high dielectric constant film, so that it is possible to efficiently etch the high dielectric constant film made of HfOₓ, HfSiOₓ, or LaOₓ.

Furthermore, in a case where hydrofluoric acid is used as the third etching liquid, it is preferable that a hydrofluoric acid concentration be from 0.57 wt % to 50 wt %, and a temperature thereof be from 15° C. to 80° C. Thus, it is possible to further efficiently etch the high dielectric constant film made of HfOₓ or HfSiOₓ.

Furthermore, in a case where sulfuric acid is used as the third etching liquid, it is preferable that a sulfuric acid concentration be from 96 wt % to 98 wt %, and a temperature thereof be from 15° C. to 80° C. Thus, it is possible to further efficiently etch the high dielectric constant film made of LaOₓ.

Furthermore, in a case where SC2 is used as the third etching liquid, a mixed ratio of “HCl:H₂O₂:H₂O” is preferably from “1:2:50” to “1:1:5”, and a temperature thereof is preferably from 15° C. to 80° C. In other words, in a case where SC2 is used as the third etching liquid, the desirable mixed ratio is from “HCl 0.80 (wt %) and H₂O₂ 1.29 (wt %)” to “HCl 5.83 (wt %) and H₂O₂ 4.72 (wt %)”. Thus, it is possible to further efficiently etch the high dielectric constant film made of LaOₓ.

Subsequent to the third etching process that has been explained so far, the controller 18 determines whether or not the third etching liquid used in the process in Step S208 is of the same kind as a fourth etching liquid for etching an interfacial oxide layer (Step S209).

In a case where the third etching liquid and the fourth etching liquid are not of the same kind (Step S209: No), the controller 18 discharges DIW onto the periphery portion of the wafer W on which the third etching process has been executed, so as to execute a rinsing process on the periphery portion of the wafer W (Step S210).

Next, the controller 18 executes a fourth etching process for etching the interfacial oxide layer exposed in the periphery portion surface of the wafer W by the third etching process (Step S211).

The fourth etching process according to the embodiment includes discharging the fourth etching liquid onto the periphery portion of the wafer W so as to etch the interfacial oxide layer located on the periphery portion. In the above-mentioned fourth etching process, in a case where the interfacial oxide layer is SiO₂, it is preferable that hydrofluoric acid be used as the fourth etching liquid.

In this case, for example, a chemical reaction expressed by the following formula (9) occurs, so that the interfacial oxide layer made of SiO₂ is efficiently etched.

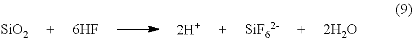

Next, the controller 18 discharges DIW onto the periphery portion of the wafer W on which the fourth etching process has been executed so as to execute a rinsing process on the periphery portion of the wafer W (Step S212). Thus, a series of periphery portion etching processes ends.

Note that in a case where the third etching liquid and the fourth etching liquid are of the same kind in the above-mentioned process in Step S209 (Step S209: Yes), the processing is shifted to Step S212.

In a case where the high dielectric constant film is HfOₓ or HfSiOₓ, for example, hydrofluoric acid is preferable as the third etching liquid for etching the above-mentioned HfOₓ or HfSiOₓ, which is the same kind as the fourth etching liquid.

In a case where the third etching liquid and the fourth etching liquid are of the same kind, in a case where the process in Step S208 is continuously executed, it is possible to continuously execute an etching process on a high dielectric constant film and an interfacial oxide layer, which are located on a surface of the wafer W. Thus, the processes in Steps S210 to S211 can be omitted.

In other words, in a case where the third etching liquid and the fourth etching liquid are of the same kind, it is possible to execute both of the third etching process and the fourth etching process by the process in Step S208.

As has been explained so far, the etching process is executed on the wafer W having a plurality of laminated functional films as illustrated in FIG. 3 while sequentially changing etching liquids appropriate for the respective functional films, so that it is possible to efficiently etch the plurality of laminated functional films.

FIG. 7 is a diagram illustrating film thicknesses of the functional films before processing, after the first etching process, after the second etching process, and after the third and fourth etching processes. In the test results illustrated in FIG. 7, the same test samples and the same film thickness gauge as those illustrated in FIG. 6 above were used.

Furthermore, in the test results illustrated in FIG. 7, in the first etching process, the first etching liquid was used, which was obtained by mixing an undiluted solution of hydrofluoric acid (50 wt %) and DIW in a volume ratio of 1:50 and by adjusting a temperature thereof to 50° C. An etching time interval of the above-mentioned first etching process was 30 seconds.

Furthermore, in the test results illustrated in FIG. 7, in the second etching process, as the second etching liquid, SC1 was used, whose mixed ratio of NH₄OH:H₂O₂:H₂O was 1:10:10, and whose temperature was 50° C. An etching time interval of the above-mentioned second etching process was 30 seconds.

Furthermore, in the test results illustrated in FIG. 7, in the third and the fourth etching processes, the third etching liquid was used, which was obtained by mixing an undiluted solution of hydrofluoric acid (50 wt %) and DIW in a volume ratio of 1:50 and by adjusting a temperature thereof to 50° C. An etching time interval of the above-mentioned third and fourth etching processes was 30 seconds.

As illustrated in FIG. 7, it can be understood that using hydrofluoric acid as the first etching liquid makes it possible to efficiently etch the work function adjusting film (see film T2 illustrated in FIG. 7) made of CeC. Furthermore, it can be understood that using SC1 as the second etching liquid makes it possible to efficiently etch the gate electrode (see a part of film T1 illustrated in FIG. 7) made of TiN.

Furthermore, it can be understood that using hydrofluoric acid as the third etching liquid makes it possible to efficiently etch the high dielectric constant film made of HfOₓ and the interfacial oxide layer made of SiO₂ (see a remaining part of film T1 illustrated in FIG. 7).

Furthermore, in the substrate processing according to the embodiment, it is preferable to sequentially execute an etching process on laminated films formed on the periphery portion and the back surface of the wafer W by using the periphery portion supply unit 40 and the back surface supply unit 50. Thus, it is possible to efficiently etch the laminated films formed on the periphery portion and the back surface of the wafer W.

In the example illustrated in FIG. 4, there is exemplified a case where the etching process is executed on the laminated films formed on both of the periphery portion and the back surface of the wafer W; however, the present disclosure is not limited to the above-mentioned example, and an etching process may be executed on one of the periphery portion and the back portion of the wafer W.

Furthermore, the etching process may be executed on a laminated film formed on a portion other than the periphery portion of the front surface of the wafer W by using the technique according to the present disclosure. Thus, it is possible to efficiently etch a laminated film formed on a portion other than the periphery portion of the front surface of the wafer W.

Furthermore, by using the technique according to the present disclosure, the first to fourth etching liquids may be retained in a plurality of respective processing tanks, and further the plurality of wafers W may be collectively immersed in the above-mentioned plurality of processing tanks, so as to execute an etching process on the plurality of wafers W in bulk.

Thus, it is possible to efficiently execute a reworking process on the plurality of wafers W in executing the reworking process on laminated films formed on the wafers W, for example.

Furthermore, in the above embodiment, there is exemplified a case where the etching process is executed on a cerium carbide film formed as a work function adjusting film of a transistor; however, the present disclosure is not limited to the above-mentioned example.

For example, by using hydrofluoric acid or SPM, it is possible to execute an etching process on a cerium carbide film formed on a substrate for the purpose that is different from adjustment of a work function. It is possible to efficiently etch a cerium carbide film by the above-mentioned procedure.

The substrate processing method according to the embodiment includes a first etching process (namely, Step S204) including supplying a first etching liquid to a substrate (namely, wafer W) on which a gate electrode and a work function adjusting film that adjusts a work function of the gate electrode, and etching the work function adjusting film. The first etching process (namely, Step S204) further includes supplying hydrofluoric acid, mixed solution of sulfuric acid and hydrogen peroxide (SPM), or mixed solution of ammonia and hydrogen peroxide (SC1) to the substrate (wafer W) as the first etching liquid. Thus, it is possible to efficiently etch the work function adjusting film on the wafer W.

Furthermore, in the substrate processing method according to the embodiment, the gate electrode includes TiN, and the work function adjusting film includes one of CeC, TiAlC, and TaC. Thus, it is possible to configure a high-performance transistor.

Furthermore, in the substrate processing method according to the embodiment, the work function adjusting film includes CeC, and the first etching process (namely, Step S204) includes supplying hydrofluoric acid to the substrate (namely, wafer W) as the first etching liquid. Thus, it is possible to efficiently etch the work function adjusting film made of CeC.

Furthermore, in the substrate processing method according to the embodiment, the work function adjusting film includes TiAlC, and the first etching process (namely, Step S204) includes supplying hydrofluoric acid to the substrate (namely, wafer W) as the first etching liquid. Thus, it is possible to efficiently etch the work function adjusting film made of TiAlC.

Furthermore, in the substrate processing method according to the embodiment, a hydrofluoric acid concentration of the first etching liquid is from 0.57 wt % to 50 wt %, and a temperature of the first etching liquid is from 20° C. to 80° C. Thus, it is possible to further efficiently etch the work function adjusting film made of CeC or TiAlC.

Furthermore, in the substrate processing method according to the embodiment, the work function adjusting film includes CeC, and the first etching process (namely, Step S204) includes supplying SPM to the substrate (namely, wafer W) as the first etching liquid. Thus, it is possible to efficiently etch the work function adjusting film made of CeC.

Furthermore, in the substrate processing method according to the embodiment, a mixed ratio of “H₂SO₄:H₂O₂” of the first etching liquid is from “1:1” to “10:1”, and a temperature of the first etching liquid is from 50° C. to 130° C. Thus, it is possible to further efficiently etch the work function adjusting film made of CeC.

Furthermore, in the substrate processing method according to the embodiment, the work function adjusting film includes TaC, and the first etching process (namely, Step S204) includes supplying SC1 to the substrate (namely, wafer W) as the first etching liquid. Thus, it is possible to efficiently etch the work function adjusting film made of TaC.

Furthermore, in the substrate processing method according to the embodiment, a mixed ratio of “NH₄OH:H₂O₂:H₂O” of the first etching liquid is from “1:1:5” to “1:10:3”, and a temperature of the first etching liquid is from 15° C. to 80° C. Thus, it is possible to further efficiently etch the work function adjusting film made of TaC.

Furthermore, the substrate processing method according to the embodiment further includes the second etching process (namely, Steps S201 and S206) including supplying a second etching liquid to the substrate (namely, wafer W), and etching the gate electrode. Furthermore, the second etching process (namely, Steps S201 and S206) includes supplying SC1 to the substrate (namely, wafer W) as the second etching liquid. Thus, it is possible to efficiently etch the gate electrode made of TiN.

Furthermore, in the substrate processing method according to the embodiment, a mixed ratio of “NH₄OH:H₂O₂:H₂O” of the second etching liquid is from “1:1:5” to “1:10:3”, and a temperature of the second etching liquid is from 15° C. to 80° C. Thus, it is possible to further efficiently etch the gate electrode made of TiN.

Furthermore, the substrate processing method according to the embodiment further includes a third etching process (namely, Step S208) including supplying a third etching liquid to the substrate (namely, wafer W), and etching a high dielectric constant film including one of HfOₓ, HfSiOₓ, and LaOₓ that is formed on the substrate (namely, wafer W). Furthermore, the third etching process (namely, Step S208) includes supplying hydrofluoric acid, a sulfuric acid, or mixed solution of hydrochloric acid and hydrogen peroxide (SC2) to the substrate (namely, wafer W) as the third etching liquid.

Furthermore, in the substrate processing method according to the embodiment, the high dielectric constant film includes LaOₓ, and the third etching process (namely, Step S208) includes supplying sulfuric acid or SC2 to the substrate (namely, wafer W) as the third etching liquid. Thus, it is possible to efficiently etch the high dielectric constant film made of LaOₓ.

Furthermore, in the substrate processing method according to the embodiment, a sulfuric acid concentration of the third etching liquid is from 96 wt % to 98 wt %, and a temperature of the third etching liquid is from 15° C. to 80° C. Thus, it is possible to further efficiently etch the high dielectric constant film made of LaOₓ.

Furthermore, in the substrate processing method according to the embodiment, a mixed ratio of “HCl:H₂O₂:H₂O” of the third etching liquid is from “1:2:50” to “1:1:5”, and a temperature of the third etching liquid is from 15° C. to 80° C. Thus, it is possible to further efficiently etch the high dielectric constant film made of LaOₓ.

Furthermore, in the substrate processing method according to the embodiment, the high dielectric constant film includes one of HfOₓ and HfSiOₓ, and the third etching process (namely, Step S208) includes supplying hydrofluoric acid to the substrate (namely, wafer W) as the third etching liquid. Thus, it is possible to efficiently etch the high dielectric constant film made of HfOₓ or HfSiOₓ.

Furthermore, in the substrate processing method according to the embodiment, a hydrofluoric acid concentration of the third etching liquid is from 0.57 wt % to 50 wt %, and a temperature of the third etching liquid is 15° C. to 80° C. Thus, it is possible to further efficiently etch the high dielectric constant film made of HfOₓ or HfSiOₓ.

Furthermore, in the substrate processing method according to the embodiment, the work function adjusting film is located to be sandwiched by the pair of gate electrodes. Thus, it is possible to configure a high-performance transistor.

Furthermore, in the substrate processing method according to the embodiment, the first etching process (namely, Step S204) further includes etching the work function adjusting film formed on at least one of an edge portion and a back surface of the substrate (namely, wafer W). Thus, it is possible to efficiently etch the work function adjusting film formed on the periphery portion and the back surface of the wafer W.

Furthermore, the substrate processing method according to the embodiment includes an etching process (namely, Step S204) including supplying an etching liquid to the substrate (namely, wafer W) on which a cerium carbide film is formed, and etching the cerium carbide film. Furthermore, the etching process (namely, Step S204) includes supplying hydrofluoric acid or mixed solution of sulfuric acid and hydrogen peroxide (SPM) to the substrate (namely, wafer W) as the etching liquid. Thus, it is possible to efficiently etch the cerium carbide film formed on the wafer W.

The embodiment according to the present disclosure is explained as described above; however, the present disclosure is not limited to the above-mentioned embodiment, and various modifications can be made to the above-described one without departing from the spirit of the present disclosure.

The embodiments disclosed here are to be considered as illustrative in all points and not restrictive. Indeed, the above-mentioned embodiment may be embodied in various forms. In addition, the above-mentioned embodiment may be omitted, replaced, or modified in various forms without departing from the scope and spirit of the appended claims.

1. A substrate processing method comprising:
a first etching process including:
supplying a first etching liquid to a substrate on which a gate electrode and a work function adjusting film are formed, the work function adjusting film adjusting a work function of the gate electrode; and
etching the work function adjusting film, wherein;
the first etching process further includes:
supplying hydrofluoric acid, mixed solution of sulfuric acid and hydrogen peroxide (SPM), or mixed solution of ammonia and hydrogen peroxide (SC1) to the substrate as the first etching liquid.

2. The substrate processing method according to claim 1, wherein
the gate electrode includes TiN, and
the work function adjusting film includes one of CeC, TiAlC and TaC.

3. The substrate processing method according to claim 2, wherein
the work function adjusting film includes CeC, and
the first etching process includes supplying hydrofluoric acid to the substrate as the first etching liquid.

4. The substrate processing method according to claim 2, wherein
the work function adjusting film includes TiAlC, and
the first etching process includes supplying hydrofluoric acid to the substrate as the first etching liquid.

5. The substrate processing method according to claim 3, wherein
a hydrofluoric acid concentration of the first etching liquid is from 0.57 wt % to 50 wt %, and a temperature of the first etching liquid is from 20° C. to 80° C.

6. The substrate processing method according to claim 2, wherein
the work function adjusting film includes CeC, and
the first etching process includes supplying SPM to the substrate as the first etching liquid.

7. The substrate processing method according to claim 6, wherein a mixed ratio of “H₂SO₄:H₂O₂” of the first etching liquid is from “1:1” to “10:1”, and a temperature of the first etching liquid is from 50° C. to 130° C.

8. The substrate processing method according to claim 2, wherein
the work function adjusting film includes TaC, and
the first etching process includes supplying SC1 to the substrate as the first etching liquid.

9. The substrate processing method according to claim 8, wherein a mixed ratio of “NH₄OH:H₂O₂:H₂O” of the first etching liquid is from “1:1:5” to “1:10:3”, and a temperature of the first etching liquid is from 15° C. to 80° C.

10. The substrate processing method according to claim 1, further comprising:
a second etching process including:
supplying a second etching liquid to the substrate; and
etching the gate electrode, wherein
the second etching process includes supplying SC1 to the substrate as the second etching liquid.

11. The substrate processing method according to claim 10, wherein
a mixed ratio of “NH₄OH:H₂O₂:H₂O” of the second etching liquid is from “1:1:5” to “1:10:3”, and a temperature of the second etching liquid is from 15° C. to 80° C.

12. The substrate processing method according to claim 1, further comprising:
a third etching process including:
supplying a third etching liquid to the substrate; and
etching a high dielectric constant film including one of HfOₓ, HfSiOₓ, and LaOₓ, the high dielectric constant film being formed on the substrate, wherein
the third etching process further includes:
supplying hydrofluoric acid, a sulfuric acid, or mixed solution of hydrochloric acid and hydrogen peroxide (SC2) to the substrate as the third etching liquid.

13. The substrate processing method according to claim 12, wherein
the high dielectric constant film includes LaOₓ, and
the third etching process includes supplying sulfuric acid or SC2 to the substrate as the third etching liquid.

14. The substrate processing method according to claim 13, wherein
a sulfuric acid concentration of the third etching liquid is from 96 wt % to 98 wt %, and a temperature of the third etching liquid is from 15° C. to 80° C.

15. The substrate processing method according to claim 13, wherein
a mixed ratio of “HCl:H₂O₂:H₂O” of the third etching liquid is from “1:2:50” to “1:1:5”, and a temperature of the third etching liquid is from 15° C. to 80° C.

16. The substrate processing method according to claim 12, wherein
the high dielectric constant film includes one of HfOₓ and HfSiOₓ, and
the third etching process includes supplying hydrofluoric acid to the substrate as the third etching liquid.

17. The substrate processing method according to claim 16, wherein
a hydrofluoric acid concentration of the third etching liquid is from 0.57 wt % to 50 wt %, and a temperature of the third etching liquid is 15° C. to 80° C.

18. The substrate processing method according to claim 1, wherein
the work function adjusting film is located to be sandwiched by the pair of gate electrodes.

19. The substrate processing method according to claim 1, wherein
the first etching process further includes etching the work function adjusting film formed on at least one of an edge portion and a back surface of the substrate.

20. A substrate processing method comprising:
an etching process including:
supplying an etching liquid to a substrate on which a cerium carbide film is formed; and
etching the cerium carbide film, wherein
the etching process further includes:
supplying hydrofluoric acid or mixed solution of sulfuric acid and hydrogen peroxide (SPM) to the substrate as the etching liquid.
